(19) United States
(12) Patent Application Publication
(10) Pub. No.: US 2006/0215795 A1
(43) Pub. Date: Sep. 28, 2006

(54) INTERFERENCE CANCELLATION OF A NARROW BANK INTERFERER IN A WIDE BAND COMMUNICATION DEVICE

(75) Inventors: Mohammed Nafie, Richardson, TX (US); Timothy M. Schmidl, Dallas, TX (US); Anand G. Dabak, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/382,580

(22) Filed: May 10, 2006

Related U.S. Application Data
(62) Division of application No. 09/772,756, filed on Jan. 30, 2001.

(51) Int. Cl. H03D 1/04

(52) U.S. Cl. 375/346

(57) ABSTRACT

Interference cancellation/suppression by a wide band radio (100) includes the steps of searching for all narrow band interferer signals such as Bluetooth signals (502). Communicating with the detected Bluetooth piconets (504). Estimating when the Bluetooth signals will occur (506) using the information received during step (504) . And using a suppression technique in association with the estimations as to when/where the interfering signals will occur in order to counter the interfering signal(s). In an alternate embodiment, both the narrow band (304) and wide band (302) signals are stored (306). Then the one or more narrow band Bluetooth signal(s) (304) and decoded (308) and subtracted (308) from the wide band packet prior to it being decoded (312).

### CROSS-REFERENCE TO RELATED APPLICATIONS

This application claims the benefit of U.S. Provisional Application No. 60/217,276, entitled “Interference Cancellation Of A Bluetooth Narrow Band Interferer”, having attorney docket No. TI-31308PS, and filed on Jul. 11, 2000.

### TECHNICAL FIELD

This invention relates in general to the field of radio communications and more specifically to interference cancellation/suppression of a narrow band interferer in a wide band communication device.

BACKGROUND

The operation of a wide band communication device can be severely affected by its proximity to one or more narrow band systems, in particular, if the narrow band system(s) have relatively high power. Given the increasing growth of narrow band systems such as frequency hopping (FHSS) spread spectrum systems like Bluetooth, there is a need in the art for a method and apparatus for canceling/suppressing the interference caused by such narrow band systems on a wide band system.

### BRIEF DESCRIPTION OF THE DRAWINGS

The features of the present invention, which are believed to be novel, are set forth with particularity in the appended claims. The invention, may best be understood by reference to the following description, taken in conjunction with the accompanying drawings, in the several figures of which like reference numerals identify like elements, and in which:

FIG. 1 shows a block diagram of a dual mode radio in accordance with the invention.

FIG. 2 highlights the technique of using a notch filter on the narrow band interferer in accordance with one aspect of the invention.

FIG. 3 highlights a joint wide band/narrow band detection technique in accordance with another embodiment of the invention.

FIG. 4 shows a block diagram of a wide band radio in accordance with another embodiment of the invention.

FIG. 5 shows a flow chart highlighting the steps taken using the dual mode radio shown in FIG. 1 in accordance with one embodiment of the invention.

### DETAILED DESCRIPTION OF THE PREFERRED EMBODIMENT

While the specification concludes with claims defining the features of the invention that are regarded as novel, it is believed that the invention will be better understood from a consideration of the following description in conjunction with the drawing figures.

Referring now to FIG. 1, there is shown a dual mode radio 100 including a wide band radio section 104 and a narrow band radio section 102. The narrow band radio section 102 in the preferred embodiment comprises a Bluetooth™ (trademark of Telefonaktiebolaget LM Ericsson Corporation) radio system. The Bluetooth system is operating in the 2.4 Giga-Hertz (GHz) ISM (Industrial Scientific Medicine) band. In a large number of countires around the world the range of this frequency band is 2400-2483.5 Mega Hertz (MHz). Channel spacing for Bluetooth is 1 MHz and guard bands are used at the lower and upper band edges (e.g., in the United States the lower guard band is 2 MHz and the upper guard band is 3.5 MHz).

The Bluetooth radio 102 can register with, receive and decode transmissions from a Bluetooth piconet. The wide band radio 104 can for example comprise a 802.11b system, a 802.11 system, or a 802.15.3 system. In the preferred embodiment, the wide band radio 104 can comprise any radio that has a wider band than the Bluetooth radio section 102. Assuming the wide band radio 104 comprises a 802.11b system, then the wide band radio comprises a spread spectrum system which covers the 2.4 GHz band.

Such a wide band radio can be used for applications such as wireless local area networks (WLAN).

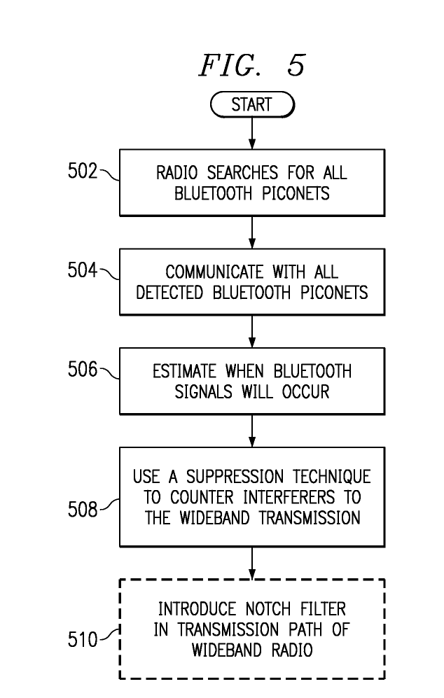

In accordance with the interference suppression/cancellation technique of the preferred embodiment, the steps shown in the flowchart of FIG. 5 are performed. In step 502, the dual mode radio 100 searches for all Bluetooth piconets in its proximity using its Bluetooth radio section 102. The Bluetooth radio section 102 scans across its receive band for potential interferers. If any Bluetooth piconets are detected in the vicinity, this information is stored in the Bluetooth radio section 102 and/or in controller 106. In step 504, dual mode radio 100 will then communicate with all of the detected piconets using the Bluetooth radio section 102 and will hence receive the clock and ID of the piconet masters for each of the Bluetooth piconets detected.

The information received from the piconet masters is then stored in either the Bluetooth radio section 102 and/or controller 106 depending on the particular design of radio 100. Controller 106 can comprise any one of a number of control circuits, including microprocessors, digital signal processors (DSPs), etc. In step 504, the Bluetooth radio section 102 can simply collect the needed information from the Bluetooth master(s) in a non-registered mode (i.e., park mode) or fully register with the detected piconets depending on the system design.

The wide band radio 104 and/or controller 106 uses the clock and the ID of the Bluetooth masters received in step 504 to estimate the hopping frequency and transmission times for all of the Bluetooth transmissions in step 506. In step 508, if the wide band radio 104 receives a transmission from another wide band radio on a frequency band that overlaps one of the Bluetooth bands that had been previously detected, it will use one of the following two suppression techniques:

1. Notch Filter

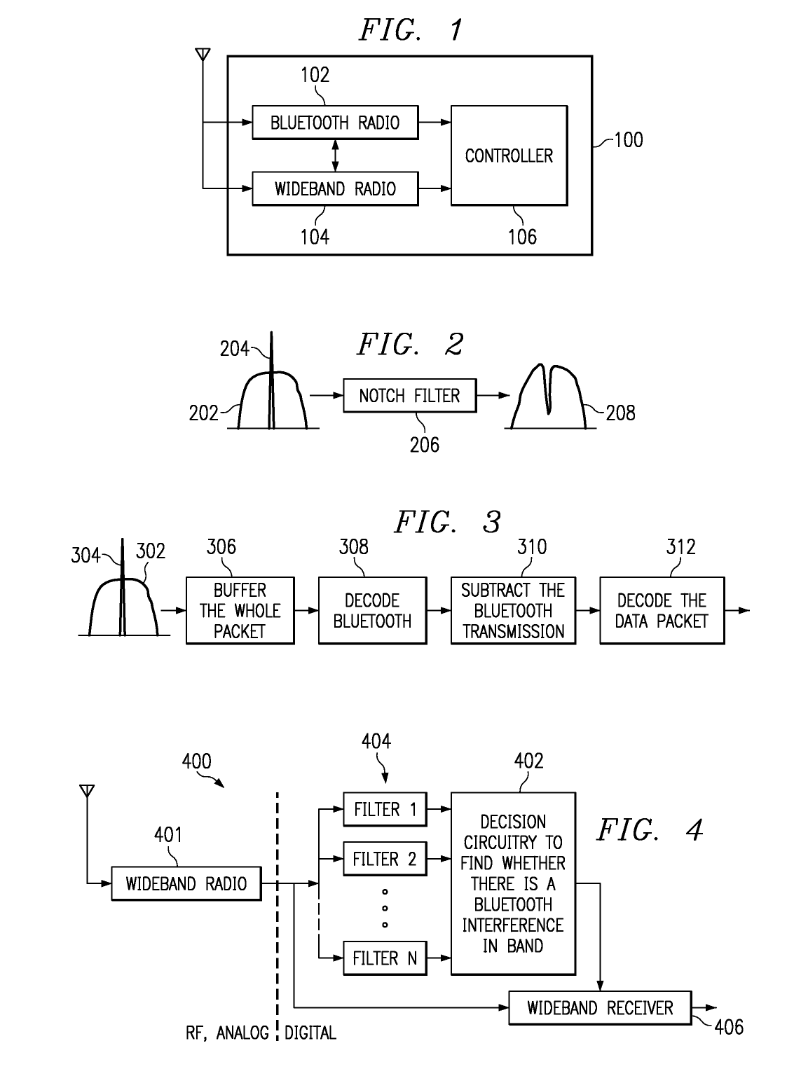

The wide band radio 104 will place a programmable notch filter(s) in the Bluetooth band(s) that will potentially interfere with the wide band radio 104 reception of wide band signals. The notch filter(s) can be implemented digitally or in analog fashion as is known in the art. In FIG. 2 there is shown a wide band transmission 202 that has been interfered with by a narrow band Bluetooth transmission signal 204. A notch filter 206 implemented within the wide band radio 104 filters out the interfering signal Bluetooth signal 204 in order to produce the resultant signal 208. The filtered signal 208 can then be properly decoded by the wide band radio 104. By registering with the potential interfering narrow band systems, radio 100 can add the notch filter(s) prior to even receiving the wide band transmission in some cases since the timing and hopping information for the interfering Bluetooth systems is known by radio 100.

2. Joint Detection

An alternative embodiment to the introduction of a filter as discussed above, is to jointly detect both the data packet that is intended for the wide band radio 104 and the Bluetooth packet(s) that have the potential of interfering with the wide band data packet. This can be done by buffering the whole packet received by the wide band radio section 104 including both the wide band 302 and narrow band 304 information as shown in block 306 of FIG. 3. Then using the Bluetooth section 102, the Bluetooth packet 304 after appropriate filtering is decoded in block 308. The Bluetooth transmission can then be subtracted from the whole packet that was received using conventional filtering or other techniques. Finally, in block 312, the wide band data packet is decoded by the wide band radio 104. As an optional step, in step 510 shown in FIG. 5, a notch filter can be placed on the wide band radio's transmitter path so that the wide band radio's transmissions do not interferer with the Bluetooth piconet that overlap (are) the wide band radio's 104 frequency band.

In a still further embodiment, instead of using a dual mode radio 100 as shown in FIG. 1, a single radio as shown in FIG. 4 is used for the wide band radio 400. In this embodiment, the wide band radio 400 can comprise as an example a 802.11, 802.11b or 802.15.3 radio system. The wide band radio 400 includes an analog front-end 401 that takes the received signal and turns it into baseband. Once the signal is at baseband, a bank of detection circuits which in the preferred embodiment comprise digital bandpass filters 404 each of bandwidth 1 MHz are employed. Based upon the output of the filter bank, the wide band receiver's digital backend 406 can determine whether a Bluetooth interference is present in the band. If there is a Bluetooth interferer, then a notch filter similar to the previous technique described above can be used to remove the Bluetooth interferer.

The decision circuitry 402 shown in FIG. 4 can employ different algorithms to detect the presence of a Bluetooth interferer signal. The decision circuitry 402 can comprise in one example, a control circuit implemented using a microprocessor, digital signal processor, etc. which can execute a decision making algorithm. One such algorithm can monitor the output power of the different digital filters in the filter bank 404. If the output power of one or more of the digital filters is very large compared to the others, then it can be inferred that there is a Bluetooth interferer in those band(s). This information is then sent to the digital backend 406 where an appropriate filter is applied to remove the unwanted narrow band signal from the already received signal.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as defined by the appended claims

1-15. (canceled)

16. A wide band radio, comprising:
a wide band radio section for receiving a wide band radio packet that can include one or more narrow band radio packets transmitted by one or more narrow band systems;
a plurality of filters each having an output, the plurality of filters are coupled to the wide band radio section; and
a decision circuit coupled to the outputs of the plurality of filters, the decision circuit monitors the outputs of the plurality of filters in order to determine if one or more narrow band packets are included with the wide band radio packet that is received by the wide band radio section, if one or more narrow band packets are detected, the decision circuit sends a signal to the wide band radio section to remove the one or more narrow band packet from the received wide band packet prior to further decoding of the wide band packet.

17. A wide band radio as defined in claim 16, wherein the decision circuit determines that a narrow band packet is in the wide band packet that is received by determining that the output of one of the bandpass filters has a power level above a predetermined level.

18. A wide band radio as defined in claim 16, wherein the one or more narrow band packets are removed using one or more notch filters.

19. A wide band radio as defined in claim 16, wherein the narrow band packets comprise Bluetooth packets.

20. A wide band radio as defined in claim 16, wherein the wide band radio section further comprises a transmitter section for transmitting wide band packets and in response to the signal provided by the decision circuit, one or more filters are added in the transmitter section's transmission path in order to minimize interfering with the one or more narrow band systems when a wide band packet is transmitted by the transmitter section.

21. A method of suppressing one or more narrow band packets that are found in a wide band packet received by a wide band radio, comprising the steps of:
(a) providing a plurality of narrow band detection circuits each one capable of detecting a narrow band packet within a portion of the wide band radio's bandwidth;
(b) determining if one of the narrow band detection circuits has detected a narrow band packet; and
(c) suppressing the one or more narrow band packets from the wide band packet if in step (b) one or more of the narrow band detection circuits has detected a narrow band packet.

22. A method as defined in claim 21, wherein the plurality of narrow band detection circuits comprises a plurality of digital filters.

23. A method as defined in claim 21, wherein each of the detection circuits has an output and in step (b) it is determined that one of the narrow band detection circuits has detected a narrow band packet by determining that it has a power level at its output above a predetermined level.
